(19) United States
(12) Patent Application Publication
(10) Pub. No.: US 2026/0362985 A1
(43) Pub. Date: Nov. 12, 2026

(54) QUANTUM MEMORY UNIT AND QUANTUM REGISTER

(71) Applicant: BADEN-WUERTTEMBERG STIFTUNG GGMBH, STUTTGART (DE)

(72) Inventors: ALEXANDER KUBANEK, ULM (DE); MARCO KLOTZ, ULM (DE); RICHARD WALTRICH, ULM (DE); ANDREAS TANGEMANN, KARLSRUHE (DE)

(73) Assignee: BADEN-WUERTTEMBERG STIFTUNG GGMBH, STUTTGART (DE)

(21) Appl. No.: 19/488,084

(22) PCT Filed: Dec. 11, 2023
(86) PCT No.: PCT/EP2023/085222

§ 371 Date: Nov. 26, 2025

(30) Foreign Application Priority Data
May 28, 2023 (WO) PCT/EP2023/064304

(51) Int. Cl. H10N 60/85

(52) U.S. Cl. CPC H10N 60/85

(57) ABSTRACT

A quantum memory unit includes a nanodiamond having a quantum emitter and a spin object which is arranged inside of or outside of the nanodiamond. An electron spin of the quantum emitter is coupled to the spin object. A coupling rate of the electron spin of the quantum emitter to the spin object is larger than a decoherence rate of the electron spin of the quantum emitter. Quantum information can be stored in the spin object, the quantum information can be retrieved from the spin object, and/or a quantum state of the spin object can be manipulated.

### CROSS REFERENCE TO PRIOR APPLICATIONS

This application is a U.S. National Phase application under 35 U.S.C. § 371 of International Application No. PCT/EP2023/085222, filed on Dec. 11, 2023 and which claims benefit to International Patent Application No. PCT/EP2023/064304, filed on May 28, 2023. The International Application was published in English on Dec. 5, 2024 as WO 2024/245586 A1 under PCT Article 21(2).

### FIELD

The present invention relates to a quantum memory unit and a quantum register.

### BACKGROUND

Many different systems are used in the prior art to realize quantum memories, however, most have the disadvantage of suffering from decoherence.

Decoherence or quantum decoherence is understood to be the loss of quantum coherence. In quantum mechanics, particles are described by a wave function. As long as there exists a definite phase relation between different states, the system is said to be coherent. This definite phase relationship is necessary to perform quantum computing on quantum information encoded in quantum states. If a quantum system were perfectly isolated, it would maintain coherence indefinitely, but it would not be possible to manipulate or investigate. If the quantum system is not perfectly isolated, for example, during a measurement, coherence is shared with the environment and appears to be lost with time. This process is called quantum decoherence or environmental decoherence.

It is known in the prior art how to produce nanodiamonds. It is known that nanodiamonds with SiV⁻ centers can be produced by chemical vapor deposition (CVD) or by a high pressure-high temperature (HPHT) fabrication method.

An aspect of the present invention is to improve upon the prior art. It is in particular an object of the present invention to supply a quantum memory unit which has a decoherence rate which is lower than in the prior art.

It is another aspect of the present invention to supply a quantum memory unit which can be efficiently coupled to flying qubits with long coherence times and which can securely store quantum information in a long-lived quantum memory inside of the quantum memory unit.

Another aspect of the present invention to supply a quantum memory unit which can be realized within a nanodiamond.

Another aspect of the present invention is to use strain, in particular intrinsic strain, within a nanodiamond to modify phonon interactions inside the nanodiamond host crystal so that decoherence of the electron spin of a quantum emitter is suppressed.

Another aspect of the present invention to provide a quantum device which can realize a quantum register, in particular perform quantum computations and realize quantum algorithms.

Another aspect of the present invention is to serve as a quantum memory unit that can be integrated into a cavity via an electromagnetic coupling, for example, an optical coupling.

In an embodiment, the present invention provides a quantum memory unit includes a nanodiamond comprising a quantum emitter and at least one spin object which is arranged inside of or outside of the nanodiamond. An electron spin of the quantum emitter is coupled to the at least one spin object. A coupling rate of the electron spin of the quantum emitter to the at least one spin object is larger than a decoherence rate of the electron spin of the quantum emitter. The at least one spin object is configured so that a quantum information can be stored in the at least one spin object, the quantum information can be retrieved from the at least one spin object, and/or a quantum state of the at least one spin object can be manipulated.

### BRIEF DESCRIPTION OF THE DRAWINGS

The present invention is described in greater detail below on the basis of embodiments and of the drawings in which:

FIG. 1 shows a schematic illustration of a quantum memory unit according to an embodiment of the present invention;

FIG. 2 shows a schematic illustration of a SiV⁻ center which is a quantum emitter known in the art;

FIG. 3 shows a schematic illustration of a SiV⁻ center which is used inside a nanodiamond, which is in turn part of a quantum memory unit according to an embodiment of the present invention;

FIG. 4 shows a schematic illustration of the electronic level structure of the SiV⁻ center of FIG. 2;

FIG. 5 shows a photoluminescence spectrum of a SiV⁻ center of a nanodiamond which is known in the prior art;

FIG. 6 shows a photoluminescence spectrum of a SiV⁻ center of a nanodiamond of a quantum memory unit according to an embodiment of the present invention;

FIG. 7 shows a partial level scheme for transition C of a SiV⁻ center of a nanodiamond of a quantum memory unit according to an embodiment of the present invention;

FIG. 8 shows transitions C1, C2, C3 and C4 of transition C of a SiV⁻ center of a nanodiamond of a quantum memory unit according to an embodiment of the present invention;

FIG. 9 shows a schematic illustration of a quantum memory unit having a spin, wherein the spin object is located outside of the nanodiamond or on the surface of the nanodiamond according to an embodiment of the present invention;

FIG. 10 shows the SiV⁻ center of FIG. 3 and illustrates the relationship between a flying photon, the electron spin of the SiV⁻ center, and the nuclear spin of the spin object;

FIG. 11 shows a sample of produced nanodiamonds on a substrate;

FIG. 12 shows an experimental setup to realize a quantum memory unit according to an embodiment of the present invention;

FIG. 13 shows a top view of a substrate including nanodiamonds as an enlarged view which is part of the experimental setup of FIG. 12;

FIG. 14 shows pulse sequences which are used to measure certain parameters of a quantum memory unit according to an embodiment of the present invention;

FIG. 15 shows a coherent population trapping (CPT) measurement of a SiV⁻ center being strongly coupled to one nuclear spin of a carbon-13 isotope to measure a coupling rate of the electron spin to the spin object and a decoherence rate of the electron spin, wherein the SiV⁻ center is part of a nanodiamond of a quantum memory unit according to an embodiment of the present invention;

FIG. 16 shows a coherent population trapping (CPT) measurement of a SiV⁻ center being coupled to two nuclear spins of two carbon-13 isotopes to measure a coupling rate of the electron spin of the SiV⁻ center to each of the three spin objects and a decoherence rate of the electron spin, wherein the SiV⁻ center and the three nuclear spins of three carbon-13 isotopes are part of a quantum register unit according to an embodiment of the present invention;

FIG. 17 shows a coherent population trapping (CPT) measurement of a SiV⁻ center being coupled to two nuclear spins of two carbon-13 isotopes to measure a coupling rate of the electron spin of the SiV⁻ center to each of the three spin objects and a decoherence rate of the electron spin, wherein the SiV⁻ center and the three nuclear spins of three carbon-13 isotopes are part of a quantum register unit according to an embodiment of the present invention;

FIG. 18 shows a schematic illustration of a quantum register unit according to an embodiment of the present invention; and FIG. 19 shows a coherent population trapping (CPT) measurement of a SiV⁻ center being weakly coupled to one nuclear spin of a carbon-13 isotope to measure a coupling rate of the electron spin to the spin object and a decoherence rate of the electron spin, wherein the SiV⁻ center is part of a nanodiamond of a quantum memory unit according to an embodiment of the present invention; and

FIG. 20 shows a coherent population trapping (CPT) measurement of a SiV⁻ center being weakly coupled to one nuclear spin of a carbon-13 isotope to measure a coupling rate of the electron spin to the spin object and a decoherence rate of the electron spin, wherein the SiV⁻ center is part of a nanodiamond of a quantum memory unit according to an embodiment of the present invention.

### DETAILED DESCRIPTION

A quantum memory unit is understood to be a device that can store and retrieve quantum information without losing coherence or fidelity on a timescale which is relevant for a specific application.

A nanodiamond may be understood to be a diamond particle which is so small that it is measured in nanometers, i.e., a size of this particle is smaller than 1000 nm. The size of a particle is understood to be the largest extent of the particle along a given axis when measured in different coordinate systems.

A quantum emitter may be understood to be a quantum system that is capable of radiative optical transitions. When observing the spontaneous decay of a single excited quantum emitter, the emission of a single photon is expected. When suppressing non-radiative decay mechanisms, a quantum emitter can principally act as 100% efficient single-photon sources. The variety of systems offered by nature allows a multitude of possible experiments and implementations of photonic applications. A quantum emitter may, for example, be a single atom in a high-finesse cavity, a colloidal nanocrystal of different size, a color center in a solid, a quantum dot, or a nanowire quantum dot structure. A quantum emitter may, for example, be used to realize a quantum bit (qubit) or to connect the states of the qubit to an optical channel. A qubit is a two-state quantum-mechanical system that can exist in a superposition of two basis states, usually denoted as |0> and |1>.

A spin object is a physical object which has the property of spin. The spin object has a magnetic moment which interacts with a magnetic field. The spin object can, for example, be or comprise an electron spin of an atom, an electron spin of a color center or a defect center, and/or a nuclear spin of an atomic nucleus. The spin object may also comprise two or more spin objects, for example, two or more electron spins which are coupled. The resulting coupled spin is called the total spin(S) or the net spin of the system. The absolute value or the modulus of the total spin S of the spin object can, for example, be one half or larger.

A spin object can be manipulated and measured by various techniques, such as electron spin resonance (ESR), which is a method that uses microwaves to induce transitions between different spin states of electrons in a sample.

The spin object may be located inside or outside of the nanodiamond. In case the spin object is located outside of the nanodiamond, the spin object can, for example, be located in the vicinity of the nanodiamond, for example, on a surface of the nanodiamond or adjacent to the surface of the nanodiamond. The term “outside of the diamond” here comprises the meaning of “on the surface of the diamond”.

The term “electron spin” is here understood to be the electron spin of the quantum emitter. The decoherence of the electron spin and the decoherence of the spin object both contribute to the decoherence rate of the coupled spin system. The decoherence of the electron spin is assumed to be the limiting factor for the decoherence of the coupled spin system. The decoherence rate of the coupled system is therefore generally referred to as the decoherence rate of the electron spin below unless stated otherwise.

The feature according to which the coupling rate of the electron spin to the spin object is larger than the decoherence rate of the electron spin means that quantum information stored inside the electron spin can be transferred to the spin object before the information stored inside the electron spin is destroyed due to the decoherence of the electron spin. This feature is necessary for quantum information to be effectively transferred between the electron spin of the quantum emitter and the spin object.

The spin object is designed and configured so that quantum information can be stored therein, be retrieved therefrom, and/or that a quantum state of the spin object can be manipulated. This feature is equivalent to a requirement which is often placed on the qubit, i.e., that quantum information can be written to the qubit, read from the qubit, and that a quantum state of the qubit can be manipulated.

This can be achieved using different methods. According to a first method using the coupling between the spin object and the electron spin of the quantum emitter, quantum information stored in the quantum emitter can be transferred to the spin object. According to a second method, a quantum state of a flying qubit can be transferred to the quantum emitter and then the quantum state of the quantum emitter can be transferred to the spin object.

A core idea of the present invention is that, on the basis of a coupling, for example, a strong coupling, between an electron spin of a quantum emitter in a nanodiamond, for example, a color center, and a spin object inside or outside of the nanodiamond, one part of this system, i.e., the spin object, is used as a long-lived quantum memory and that the other part of the system, i.e., the quantum emitter in the nanodiamond, is used as a possible quantum communication device to the outside world, for example, a flying qubit. The advantages here are, as already mentioned, that the electron spin of the quantum emitter can easily exchange quantum information from outside the nanodiamond, for example, with a flying qubit. The quantum emitter inside the nanodiamond acts as a quantum communication interface to the world outside of the nanodiamond. The spin object inside the nanodiamond is shielded quite well from the outside world, i.e., the decoherence rate of the quantum state of the spin object is lower than a decoherence rate which other quantum objects experience which are around the spin object.

A further advantage of the present invention is that the coupling of the electron spin of the quantum emitter and the spin object enables an effective exchange of quantum information between the electron spin of the quantum emitter and the long-lived and well-isolated spin object.

Yet another advantage of the present invention is that the quantum memory unit, in particular the spin object of the quantum memory unit, may be integrated inside a solid-state matrix, i.e., in this case a diamond, having dimensions so that external coupling, for example, optical coupling, may be enabled effectively.

Another advantage of the present invention is that an efficient external coupling, in particular of the spin object, enables efficient information transfer, in particular of the spin object to, for example, a flying qubit or another spin object inside or outside of the nanodiamond.

Yet another advantage of the present invention is that the small size of the nanodiamond or quantum memory unit enables an integration of the quantum memory unit into a device such as, for example, a tailored photonic and/or microwave structure.

A further advantage of the present invention is that the small size of the nanodiamond or quantum memory unit enables the suppression of electron phonon coupling, thus improving electron spin coherence times.

In an embodiment of the present invention, the quantum memory unit the spin object can, for example, be a non-zero nuclear spin of an atom. The atom may be an atom of the nanodiamond, i.e., inside of the nanodiamond, or may be outside of the nanodiamond.

An advantage of the present feature is that the quantum information stored inside a nuclear spin is well isolated from its environment, which means that the decoherence rate of the quantum information stored inside the nuclear spin is very low. A nuclear spin can generally be well isolated from the environment since an interaction rate with the spin environment is smaller than a corresponding interaction rate of an electron spin. This is due to the fact that the magnetic moment of a nuclear spin is smaller than the magnetic moment of an electron spin. The environment in a diamond can also be isotopically purified further, thereby reducing environmentally induced decoherence mechanisms. This enables very long storage times, for example, longer than 1 ms.

As the quantum emitter is located within a diamond matrix of the nanodiamond, the concentration of the spin object density, for example, carbon-13 isotopes, in the environment can be controlled during nanodiamond synthesis.

There are not, for example, too many spin objects inside the nanodiamond so that it is still possible to resolve them. There are not, for example, too few spin objects inside the nanodiamond so that there are still enough spin objects to observe.

There can, for example, be few spin objects inside the nanodiamond having different coupling strengths, each spin object being coupled to the electron spin of the quantum emitter because a quantum register of qubits can thereby be realized. This will be explained further below.

The atom can, for example, be a carbon-13 isotope, a Si-29 isotope, a N-15 isotope, or an atom inside or outside of the nanodiamond having a non-zero nuclear spin.

In an embodiment of the quantum memory unit of the present invention, the spin object can, for example, be an electron spin object. An electron spin object is understood to be an object which comprises an electron spin resulting from either a single electron spin or coupled multiple electron spins.

In the absence of a magnetic field, the ground state of the quantum emitter is energetically split due to interactions of the electron spin of the quantum emitter and its orbital angular momentum, as well as due to interactions of its orbital angular momentum with static strain. This energetic difference is referred to as orbital ground state splitting.

In the presence of a magnetic field, the aforementioned orbital ground states split into spin states, due to interactions of the spin states magnetic moment with the external magnetic field, referred to as spin state splitting. The spin states split further into composite spin states due to interactions with the magnetic moment of the spin object or spin objects.

The respective energy differences are referred to as composite spin state splitting. If the spin object is a nuclear spin, this composite spin state splitting corresponds to the hyperfine splitting.

A magnetic field strength inside the nanodiamond can, for example, be larger than 50 mT. The magnetic field strength inside the nanodiamond can, for example, be larger than 300 mT. The magnetic field inside the nanodiamond can, for example, be generated, for example, by four permanent magnets in a Halbach configuration or a Halbach array. The Halbach configuration is designed for a field strength of around 400 mT, i.e., for example, between 390 and 410 mT.

A subset of two states of the spin states or the composite spin states may be used as a qubit.

The quantum state of the qubit can directly and/or indirectly be manipulated and controlled via electromagnetic interactions, for example, optical and/or microwave and/or RF frequency waves.

The term optical control comprises coupling the two qubit states using a Raman transition via an excited state. The energy difference between the qubit state and the aforementioned excited state may be in the optical range.

In an embodiment of the present invention, a strain of the nanodiamond can, for example, be larger than a predetermined value so that a ground state splitting, for example, an orbital ground state splitting, is larger than 46 GHz. This value refers to a quantum memory unit wherein the quantum emitter is a SiV⁻ center. This feature advantageously achieves a reduction of a decoherence rate of the electron spin of the quantum emitter, in particular to a value less than 4 MHz. This can, for example, be achieved at a temperature of 4K. The phonon absorption rate at liquid Helium temperature is ultimately the limiting factor for an electron spin decoherence rate. The phonon absorption rate is a function of the orbital ground state splitting, which depends on the strain.

The electron spin coherence time T2 in a quantum emitter, in particular a color center, is the characteristic time for the loss of phase coherence of the electron spin in the presence of a magnetic field.

If the dimensions of the nanodiamond gets smaller, then the orbital T1 time could get longer if the resulting cut-off frequency in the phonon density of states starts to influence the phonon occupation at the relevant phonon energy. An increased orbital T1 could lead to an increase in the electron spin coherence time T2.

The T1 time is the characteristic time for the relaxation into thermal equilibrium of the ground state. The orbital T1 time is the characteristic time for the relaxation into thermal equilibrium of the orbital ground state. The spin T1 time is the characteristic time for the relaxation into thermal equilibrium of the spin ground state.

The decoherence rate of an electron spin in a nanodiamond at liquid helium temperature is mainly limited through phonon-mediated decoherence.

The phonon-mediated decoherence can be improved by either cooling the nanodiamond to mK temperatures, thereby changing a phonon-density of states (PDOS), or by increasing a ground state splitting of the quantum emitter which suppresses phonon absorption. The PDOS is a function that describes the number of vibrational modes or phonons per unit frequency range in a solid or a liquid.

The strain of the nanodiamond can, for example, be larger than another predetermined value so that a ground state splitting, for example, an orbital ground state splitting, is larger than 0.5 THz. This feature advantageously achieves a further reduction of the decoherence rate of the electron spin of the quantum emitter.

For an orbital ground state splitting larger than 0.5 THz, the corresponding electron spin coherence rate Γ₂ can be smaller than 320 kHz. This was extrapolated from coherent population trapping (CPT) measurements.

For an orbital ground state splitting larger than 1 THz, the corresponding electron spin coherence rate Γ₂ can be smaller than 160 kHz. This was extrapolated from a Ramsey measurement. The corresponding electron spin coherence rate Γ₂ extrapolated from a Hahn-Echo measurement can be smaller than 16 kHz. The electron spin coherence rate Γ₂ extrapolated from a XY-N measurement can be smaller than 5 kHz.

The above-mentioned feature advantageously achieves that phonon absorption of the quantum emitter is reduced, which in turn reduces the decoherence of the quantum emitter, in particular the decoherence of a qubit which is realized through the quantum emitter.

In an embodiment of the present invention, a size of the nanodiamond can, for example, be smaller than a wavelength of an optical transition of the quantum emitter.

This feature advantageously achieves that an electric field can efficiently be coupled to the quantum emitter, which is located inside the nanodiamond. The electric fields can be the electric field of a resonator or a cavity. This means that a flying qubit can be efficiently coupled to the quantum emitter.

The size of the nanodiamond can, for example, be smaller than 100 nm. The size of the nanodiamond can, for example, be smaller than 30 nm.

Alternatively or additionally to the above-mentioned embodiment, the size of the nanodiamond can, for example, be smaller than a wavelength of a phonon in the nanodiamond corresponding to an energy of the ground state splitting.

This causes the PDOS either to comprise a monotonically increasing behavior with a step-like cut-off frequency so that the PDOS below the cut-off frequency is suppressed compared to a bulk diamond or to comprise spectral regions where the PDOS is suppressed compared to a bulk diamond. The transition frequency corresponding to the quantum emitter's orbital ground-state splitting is here smaller than the aforementioned cut-off frequency or within the spectral regions. This has the effect that basically no phonons will be absorbed by the transition between the ground states. A phonon corresponding to an energy of the ground state splitting cannot therefore propagate inside the nanodiamond because of the small size of the nanodiamond. There is therefore a reduced number of phonons inside the nanodiamond which can drive transition between the ground states. The above mentioned feature advantageously therefore achieves that phonon absorption of the quantum emitter is reduced which makes the orbital T1 time longer and reduces decoherence of the quantum emitter, in particular decoherence of a qubit which is realized through the quantum emitter.

In an embodiment of the present invention, the quantum emitter can, for example, be a group IV color center, for example, a single negatively charged silicon vacancy SiV⁻ center.

While first small networks, for example, based on negatively-charged nitrogen vacancy center in diamond (NV⁻) , have been realized in pioneering work, NV⁻ is prone to perturbations from external fields and only has a low rate of coherent photons.

In contrast thereto, group IV defects, in particular the negatively-charged silicon vacancy center (SiV⁻) , have the advantage that the atomic transition frequencies are insensitive to external electric fields and have intrinsically identical emitters. The use of the single negatively charged silicon vacancy SiV⁻ center is advantageous because it has a higher emission rate, a narrower linewidth, and a better spectral stability.

In an embodiment of the present invention, the quantum memory unit can, for example, further comprise a second spin object outside of the nanodiamond, wherein the electron spin of the quantum emitter is coupled to a spin of the second spin object and wherein a coupling rate of the spin of the spin object to the electron spin of the quantum emitter is larger than a decoherence rate of the electron spin of the quantum emitter.

Using the coupling of the second spin object outside of the nanodiamond to the electron spin of the quantum emitter inside the nanodiamond has the advantage that the quantum information stored inside the nanodiamond can be coupled to external quantum platforms such as, for example, superconducting technology, thereby creating an interface between different processor units and/or memory units.

Another advantage of the present feature is that the coupled spin object does not necessarily couple to an optical field or more generally to an electromagnetic field. This is advantageous because of lower decoherence.

The second spin object can, for example, be located in the vicinity of the nanodiamond, for example, on a surface of the nanodiamond or adjacent to the surface of the nanodiamond.

The second spin object outside of the nanodiamond could, for example, be a magnetic nanoparticle, a single molecule magnet, or a nuclear spin.

In an embodiment of the present invention, the coupling rate of the electron spin to the spin object can, for example, be larger than 0.01 MHz, for example, larger than 0.1 MHz, for example, larger than 5 MHz. This coupling can, for example, be larger than 40 MHz.

The advantage of this feature is that for a strong coupling rate, the indirect manipulation of the spin object via the electron spin can be performed at faster time scales.

A further advantage of this feature is that for a given decoherence rate, a larger coupling strength increases the maximum number of operation cycles per decoherence time.

Yet another advantage of this feature is that spin objects can be detected more easily without the need for decoupling schemes and without extending the electron spin decoherence time.

In an embodiment of the present invention, a decoherence rate of the electron spin can, for example, be smaller than an electron spin flip rate under driving. The electron spin flip rate under driving is a measure of how fast the spin state of an electron changes when it is subjected to an external driving force, such as an electric field, for example, an electromagnetic pulse, a magnetic field, and/or an optical field. This feature advantageously achieves that quantum information stored inside the electron spin can be processed efficiently because the processing speed, i.e., the electron spin flip rate, is faster than the decoherence rate, which includes spontaneous emission as a limiting factor.

In a quantum memory unit comprising a SiV⁻ center as a quantum emitter, the electron spin flip rate under driving can, for example, be approximately 10 MHz, for example, between 5 and 15 MHz.

In an embodiment of the present invention, a transition of the quantum emitter can, for example, be driven by microwave radiation and/or by optical radiation. Microwave and optical radiation are widespread standard means.

For the case of a nanodiamond comprising a single negatively charged silicon vacancy SiV⁻ center as a quantum emitter whose electron spin is coupled to a nuclear spin of a carbon-13 isotope, the decoherence rate of the electron spin can, for example, be smaller than 320 kHz. This value is an actual measurement of the present invention. This is approximately a ten-fold reduced decoherence rate compared to known prior art measurements in bulk diamond at similar temperatures whose decoherence rate is 4.5 MHz.

In an embodiment of the present invention, the quantum memory unit can, for example, be designed and configured so that, in order to measure the decoherence rate of the electron spin, a pulse sequence and/or a dynamical decoupling sequence is applied to the quantum memory unit, and that a measured decoherence rate of the electron spin is smaller than 1 MHz. This feature advantageously achieves that a lower decoherence rate of the electron spin can be measured.

The coupling rate of the electron spin to the spin object is larger than the decoherence rate of the electron spin. If the decoherence rate of the electron spin decreases, then a number of detectable spin objects in a given sample size, for example, the nanodiamond, increases. The number of detectable spin objects in a given sample size corresponds to the number of spin objects having coupling rates larger than the decoherence rate of the electron spin of the quantum emitter. Not only the number of detectable spin objects here increases, but at the same time the quantum memory is more long-lived because the decoherence rate is lower. In summary, this has the advantage that a lower decoherence rate can be measured and at the same time more spin objects become available for measurement.

The coupling rate of the electron spin of the quantum emitter to the spin of the spin object can, for example, be smaller than 1 MHz. The coupling rate of the electron spin of the quantum emitter to the spin of the spin object can, for example, be smaller than 1 kHz. The spin object can, for example, be a nuclear spin inside the nanodiamond.

The pulse sequence and/or the dynamical decoupling sequence can, for example, be a Hahn-echo sequence, a CPMG sequence, and/or a XY-N sequence. The CPMG sequence (Carr-Purcell-Meiboom-Gill sequence) is a method used in NMR spectroscopy and magnetic resonance imaging (MRI).

According to another embodiment a temperature of the nanodiamond is above 100 mK. This feature advantageously achieves that the cooling requirements are less severe than cooling to mK temperatures. The temperature of the nanodiamond can, for example, be above 5K. This feature advantageously achieves that the cooling requirements are even less severe because liquid helium can be used to achieve this temperature range. The temperature of the nanodiamond can, for example, be above 70 K. This feature advantageously achieves that the cooling requirements are even less severe because liquid nitrogen can be used to achieve this temperature range.

In an embodiment of the present invention, the quantum memory unit, in particular the electron spin of the quantum emitter and/or the spin object, can, for example, be designed and configured so that the quantum state of the spin object can be coherently manipulated and/or controlled by coherently controlling the electron spin of the quantum emitter and/or by applying microwave or RF radiation to the spin object.

This feature advantageously achieves that the quantum state of the spin object, which is used to store quantum information for a long time, can be brought into a predetermined state having an arbitrary relative amplitude and phase.

For the case that the spin object is a spin ½ particle or a two level system, an arbitrary state of the spin object is equivalent to an arbitrary point on the Bloch sphere.

The meaning of the term “coherently manipulating” is that the quantum state is changed so that the coherence is preserved.

According to a first alternative, the quantum state of the spin object is coherently manipulated and/or controlled by coherently controlling the electron spin of the quantum emitter. This feature is enabled by the coupling between the electron spin of the quantum emitter and the spin object. As stated above, the quantum emitter can communicate with a flying qubit, while the spin object inside the nanodiamond is shielded quite well from the environment except for the coupling to the quantum emitter. Expressed differently, the electron spin of the quantum emitter acts as a kind of intermediary, mediator, or broker between a flying qubit coming from outside of the nanodiamond and the spin object inside the nanodiamond.

Via the coupling between the electron spin of the quantum emitter and the spin object, the quantum state of the spin object may be controlled by the state of the quantum emitter. The electron spin of the quantum emitter may be coherently manipulated and/or controlled using an all-optical method or using microwave radiation. An all-optical method refers to a technique that uses light for both the input and output without the need for electronic data conversion. Using an all-optical method or microwave radiation is a big advantage because these are widely used methods which are easy to use. The quantum state of the spin object is coherently manipulated and/or controlled indirectly according to this method. This indirect driving has the advantage that the spin object can be manipulated faster because of an increased coupling of the electron spin to the external driving field. It is also advantageously achieved that less driving power is required for the same reason.

Another advantage is that the electron spin can be decoupled during the manipulation of the spin object. This advantageously achieves that the decoherence of both the electron spin and the spin object are improved.

The first alternative may be realized by directing or shining optical light onto the quantum emitter. The atomic transition may in this case be driven directly.

According to a second alternative, the quantum state of the spin object is coherently manipulated and/or controlled by applying microwave or RF radiation to the spin object. The quantum state of the spin object is here coherently manipulated and/or controlled directly.

This direct manipulation has the advantage that the electron spin of the quantum emitter can be controlled more independently from the manipulation of the spin object, with less effect, on the quantum state of the spin object.

A further advantage of the direct manipulation is that the driving sequence is generally simpler, has fewer required steps, and therefore may be performed easier.

In an embodiment of the present invention, the electron spin of the quantum emitter and the spin object can, for example, be designed and configured so that quantum information can be transferred from a flying qubit to the spin object and/or from the spin object to the/a flying qubit.

If quantum information is transferred from the flying qubit to the spin object, this transfer is mediated by the coupling of the electron spin of the quantum emitter to both the photon of the flying qubit and to the spin object. This also means that the electron spin of the quantum emitter and the spin object can become entangled.

This feature advantageously achieves that quantum information processing can be performed via coherent optical fields without the need to transfer quantum information to single photon states.

The transfer of an arbitrary entangled state, for example, of the electron spin and the spin object, on to single photon states has the advantage that different quantum memory units can be connected and/or entangled. A single photon can be used as a mediator between two different quantum memory units.

The present invention further provides a quantum register unit.

The quantum register unit comprises a quantum memory unit as described above. While the quantum memory unit comprises a spin object inside or outside of the nanodiamond, the quantum register unit in contrast comprises at least two spin objects.

The electron spin of the quantum emitter is also coupled to the at least two spin objects. The at least two spin objects are here different spin objects inside and/or outside of the nanodiamond. A coupling rate of the electron spin to each of the at least two spin objects is also larger than the decoherence rate of the electron spin. Each spin object of the at least two spin objects is designed and configured so that quantum information can be stored therein, retrieved therefrom, and/or that a quantum state of that spin object can be manipulated.

A quantum register is understood to be a system comprising at least two qubits. It is the quantum analogue of the classical processor register. Quantum computers perform calculations by manipulating qubits within a quantum register. While a classical register having n bits is able to store a single value between 0 and 2ⁿ−1, a quantum register is able to store a superposition of all these values at the same time.

This feature advantageously achieves that a quantum register is realized which can be used to realize quantum computations and quantum algorithms, a quantum node, a quantum network and/or a quantum communication system.

The at least two spin objects here correspond to the quantum register.

A subset of all quantum states of the quantum register or all quantum states can be achieved using the coupling of the electron spin of the quantum emitter to each of the at least two spin objects.

In an embodiment of the quantum register unit of the present invention, at least one of the at least two spin objects can, for example, be coupled to at least another one of the at least two spin objects. A coupling rate between the at least one of the at least two spin objects and the at least another one of the at least two spin objects is here larger than the largest decoherence rate of the at least two spin objects.

As used below, the term “at least two spin objects” may alternatively be called total number of spin objects, the term “at least one of the at least two spin objects” may alternatively be called a first number and the term “at least another one of the at least two spin objects” may alternatively be called a second number.

If either the first number or the second number is larger than two, then the term “a coupling rate” refers to at least two coupling rates. All coupling rates between the first number of spin objects and the second number of spin objects are in this case required to be larger than the largest decoherence rate of the total number of spin objects.

The coupling between the at least one of the total number of spin objects and the at least another one of total number of spin objects advantageously achieves that quantum information can be exchanged between the at least one of the total number of spin objects and the at least another one of the total number of spin objects. This implies that the at least one of the total number of spin objects and the at least another one of the total number of spin objects can become entangled.

The advantage over the previous stated embodiment is that the additional coupling or the additional couplings allow a faster and/or more direct manipulation of the quantum state of the at least two spin objects.

As stated above the spin object can, for example, be or comprise an electron spin of an atom, an electron spin of a quantum emitter, in particular of a color center or a defect center, and/or a nuclear spin of an atomic nucleus. In an embodiment of the quantum register unit of the present invention, the spin object can, for example, be a nuclear spin, in particular a nuclear spin of a carbon-13 isotope.

Embodiments of the present invention are shown in the drawings and will be explained in greater detail below.

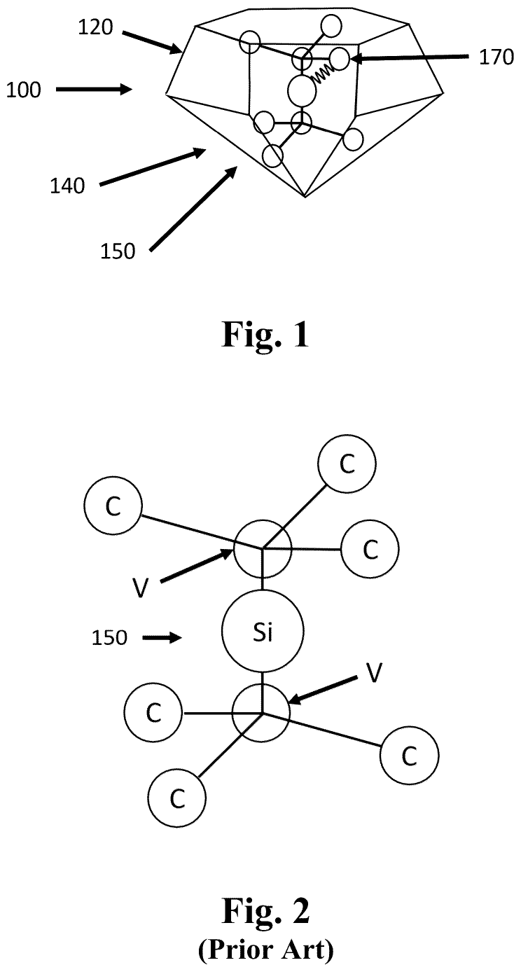

FIG. 1 shows a schematic illustration of a quantum memory unit 100 comprising a nanodiamond 120 having a single negatively charged silicon vacancy (SiV⁻) center 150 as a quantum emitter 140.

The SiV⁻ center 150 as depicted in FIG. 2 is a known quantum emitter 140 in the prior art. FIG. 2 shows a point defect in the lattice of a diamond crystal where one silicon atom Si is replacing two carbon atoms C and where the silicon atom Si is located between two adjacent vacant lattice sites V.

The SiV⁻ center 150 can be thought of an artificial atom. The electronic level structure of the SiV⁻ center 150 is illustrated in FIG. 4. The level scheme of the SiV⁻ center 150 comprises four spin-degenerate orbital states, two of which form the ground-state 200 and excited-state 210, respectively. The zero-phonon line (ZPL) between the ground state 200 and the excited state 210 has roughly 1.68 eV.

Both the ground state 200 and the excited state 210 show a level splitting due to spin orbit coupling. Both the ground state 200 and the excited state 210 therefore have doublets which are separated by ΔGS and ΔES, respectively. The ground state splitting ΔGS is about 46 GHz, while the excited state splitting ΔES is about 252 GHz. The ground state 200 has a lower ground state 202 and an upper ground state 204. The lower ground state 202 and the upper ground state 204 are also called orbital ground states. The splitting between the lower ground state 202 and the upper ground state 204 may be called ground state splitting or orbital ground state splitting. The excited state 210 has a lower excited state 212 and an upper excited state 214. The lower excited state 212 and the upper excited state 214 are also called orbital excited states. The splitting between the lower excited state 212 and the upper excited state 214 may be called excited state splitting or orbital excited state splitting.

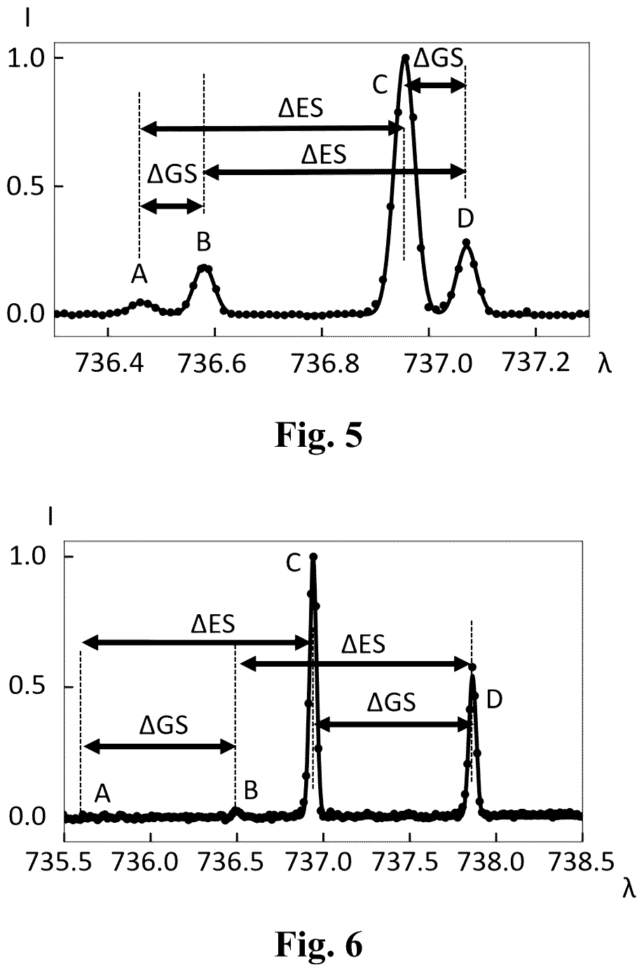

These level splittings result in four optically active transitions, which can be observed at cryogenic temperatures. These transitions are A, B, C, D, which are depicted for a SiV⁻ center 150 with low strain in FIG. 5. Transition D is between the lower excited state 212 and the upper ground state 204, transition C is between the lower excited state 212 and the lower ground state 202, transition B is between the upper excited state 214 and the upper ground state 204, transition A is between the upper excited state 214 and the lower ground state 202. For the present case of a SiV⁻ center 150 in a nanodiamond 120 with low strain, the wavelengths of the transitions A, B, C, D lie between 736 and 737 nm, wherein transition A has the smallest wavelength and transition D has the largest wavelength. The wavelength of the transition C is around 736.75 nm.

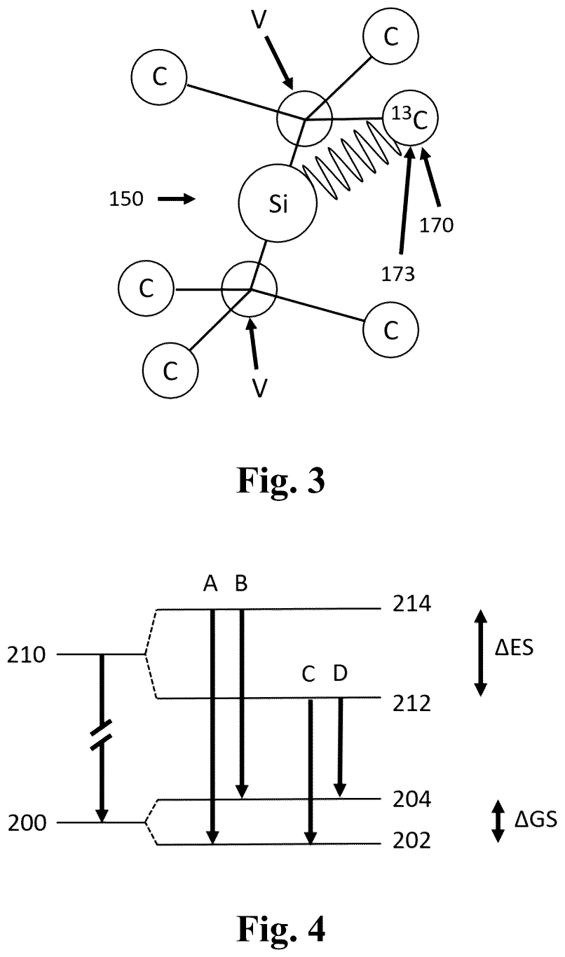

The quantum memory unit 100 of the embodiment of FIG. 1 comprises a SiV⁻ center 150 which differs from the SiV⁻ center 150 of FIG. 2 in at least two features and is shown in FIG. 3. An electron spin of the SiV⁻ center 150 is here coupled to a spin object 170 inside of the nanodiamond 120. According to the embodiment of FIG. 1, the spin object 170 is a nuclear spin of a carbon-13 isotope 173 which is one of the carbon atoms C which is adjacent to one vacant lattice site V, as can be seen in FIGS. 1 and 3. The nuclear spin of the carbon-13 isotope 173 is −½. The wavy line between the SiV⁻ center 150 and the carbon-13 isotope 173, which is shown in FIGS. 1 and 3, symbolizes the coupling between the SiV⁻ center 150 and the spin object 170, i.e., the carbon-13 isotope 173. The strain inside the nanodiamond 120 is so large that the ground state splitting is in the order of 500 GHz, for example, between 450 and 550 GHz. This strain inside the nanodiamond 120 is graphically represented in FIG. 3 by the fact that the axis between the two adjacent vacant lattice sites V, where also the silicon atom Si is located, is drawn rotated, sheared or tilted with respect to the drawing of FIG. 2.

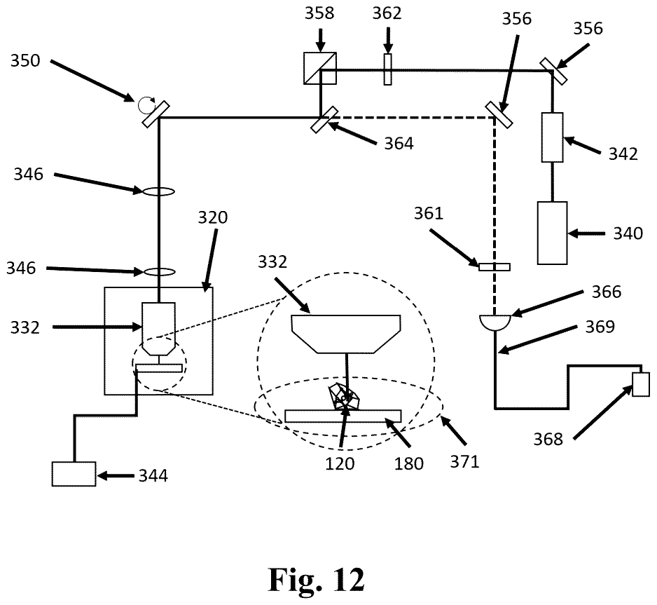

The SiV⁻ centers 150 used in the embodiments presented here are located inside nanodiamonds 120 which have sizes between 20 nm and 1000 nm. The nanodiamonds 120 are produced and coated onto a sapphire substrate 180 to provide good thermal conductivity (see FIG. 11). An atomic force microscope scan of the nanodiamonds 120 containing the investigated the SiV⁻ center 150 revealed an agglomeration of nanodiamonds 120 having a size of approximately 600 nm. The SiV⁻ center 150 used in the experiment and measurements of FIGS. 12, 13, 15 to 17, 19 and 20 was located inside this agglomeration of nanodiamonds 120. As the wavelengths of the transitions C, D lie between 730 and 750 nm, the size of the nanodiamond 120 of the embodiment of FIG. 1 is smaller than a wavelength of an optical transition of the quantum emitter 140. The wavelength of a phonon in a nanodiamond 120 whose ground state splitting is 500 GHz is approximately 25 nm.

A photoluminescence spectrum of the SiV⁻ center 150 of FIG. 2 having the atomic level structure of FIG. 4 is shown in FIG. 5. A continuous-wave 532 nm laser may be used to excite the individual color centers off-resonantly. FIG. 5 shows the intensity I in relative units as a function of the emitted wavelength λ. The four peaks correspond to the four transitions A, B, C, and D. The wavelength difference between transitions B and A and transitions D and C corresponds to AGS of FIG. 4, and the wavelength difference between transitions C and A and transitions D and B corresponds to ΔES of FIG. 4.

FIG. 6 shows a photoluminescence spectrum of the SiV⁻ center 150 of FIG. 3 with increased strain inside the nanodiamond 120. Like in FIG. 5, FIG. 6 shows the intensity I in relative units as a function of the emitted wavelength λ. The ground state splitting AGS is here approximately 510 GHz. Due to the high strain, phonic processes from the upper excited state 214 to the lower excited state 212 are faster than the optical lifetime, i.e., smaller than 1.7 ns. This makes the transitions from the upper excited state 214 to the upper ground state 204 or from the upper excited state 214 to the lower ground state 202 improbable, which is why the characteristic lines A and B are barely visible or not visible at all in the spectrum. For the present case of a SiV⁻ center 150 with increased strain, the wavelengths of the transitions C and D here lie between 730 and 750 nm.

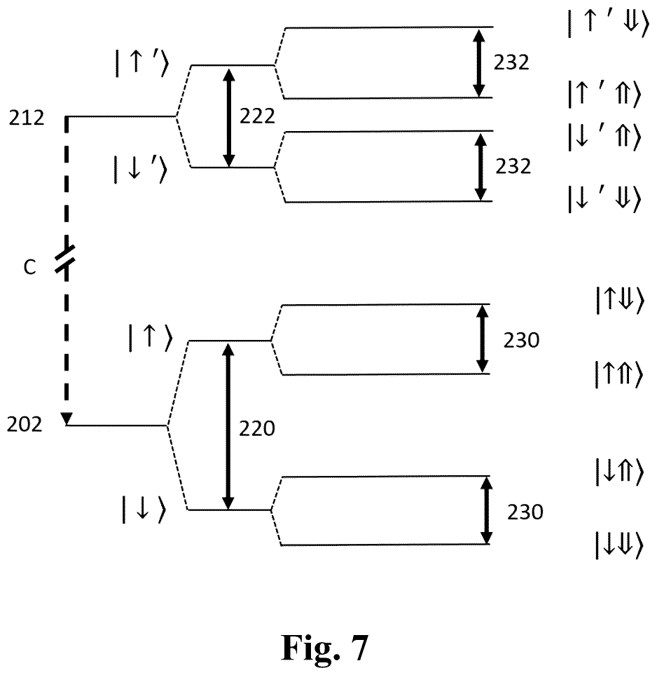

As the SiV⁻ center 150 of the quantum memory unit 100 is coupled to the nuclear spin of a carbon-13 isotope 173, the level scheme of FIG. 4 needs to be modified as shown in FIG. 7. FIG. 7 shows the spin levels of transition C because the embodiments presented here only use transition C.

The spin degeneracy of the levels of the ground state 200 and of the levels of the excited state 210 can be lifted by applying a magnetic field. Four permanent magnets in a Halbach configuration which generate a magnetic field strength inside the nanodiamond of around 400 mT are used to lift the spin degeneracy.

The left side of FIG. 7 shows that transition C connects levels of the lower excited state 212 with levels of the lower ground state 202.

Each of those two levels, i.e., 202 and 212, split into two levels in a magnetic field according to the well-known Zeeman effect. This splitting is due to the spin orbit interaction between the electron spin of the SiV⁻ center 150 and the orbital states of the SiV⁻ center 150.

The lower ground state 202 splits into a spin down state |↓ [symbol] and a spin up state |η [symbol] . The spin is here the electron spin of the quantum emitter. The lower excited state 212 splits into a spin down state |↓′ [symbol] and a spin up state |↑′ [symbol] .

The splitting between the spin down state |↓ [symbol] and the spin up state |↑ [symbol] may be called ground state spin spitting 220. The splitting between the spin down state |↓′ [symbol] and the spin up state |↑′ [symbol] may be called excited state spin spitting 222.

Due to the coupling of the electronic spin of the SiV⁻ center 150 to the spin object 170, i.e., nuclear spin of a carbon-13 isotope 173, these levels will each split into two further states. The electronic spin of the quantum emitter 140 will then couple with the additional other spin to form a so-called composite spin. The nuclear spin is illustrated in FIG. 7 with double arrow symbols, wherein [symbol] indicates a spin up state of the nuclear spin and [symbol] indicates a spin down state of the nuclear spin. The right-hand side of FIG. 7 indicates the composite spin states using ket vectors, for example, if the composite spin is made up of a spin down state of the electron spin of the SiV⁻ center 150 and the spin down state [symbol] of the nuclear spin, then the ket vector is written like that: |↓ [symbol] [symbol] . The other combinations of the electron spin and the nuclear spin can be seen on the right-hand side of FIG. 7. The level structure on the right-hand side of FIG. 7 which stem from the interaction of the spin electronic spin is called hyperfine structure, which is well known in the art.

The splitting between the hyperfine levels |↓ [symbol] [symbol] and |↓ [symbol] > may be called ground state composite spin spitting 230 because these two states split from the spin down state |↓ [symbol] due to the interaction of the nuclear spin with the electron spin. The splitting between the hyperfine levels |↑ [symbol] [symbol] and |↑ [symbol] [symbol] may also be called ground state composite spin spitting 230 because these two states split from the spin up state |↑ [symbol] due to the interaction of the nuclear spin with the electron spin. The splitting between the hyperfine levels |↓′ [symbol] [symbol] and |↓′ [symbol] [symbol] and between the hyperfine levels |↑′ [symbol] [symbol] and |↑′ [symbol] [symbol] may accordingly be called excited state composite spin spitting 232.

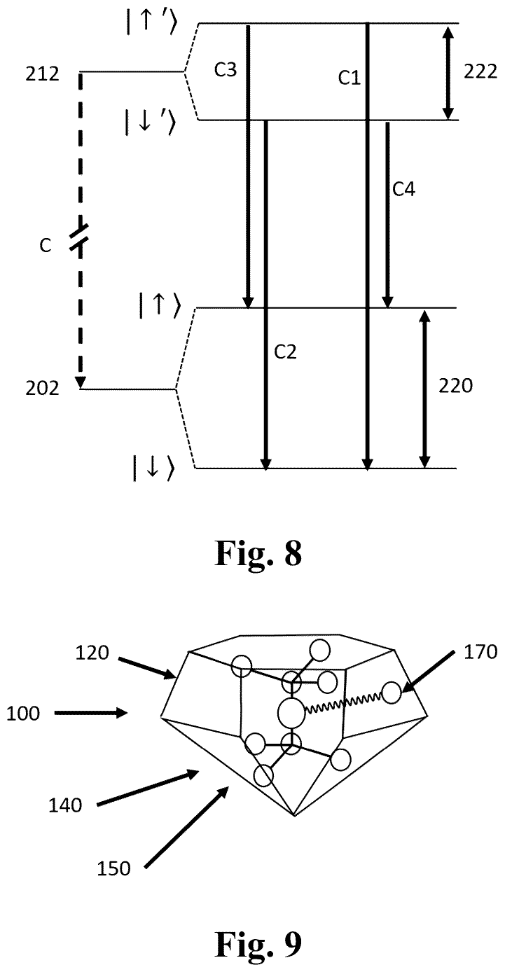

Due to the spin orbit interaction, the transitions A, B, C and D split into a plurality of lines. As in embodiments presented here, only transition C is used; FIG. 8 shows the splittings of transition C. Transition C is split into 4 transitions C1, C2, C3 and C4. The transitions C2 and C3 are spin-preserving transitions. Transition C2 is between the spin down state |↓′> of the lower excited state 212 and the spin down state |↓ [symbol] of the lower ground state 202. Transition C3 is between the spin up state |↑′> of the lower excited state 212 and the spin up state |↑ [symbol] of the lower ground state 202. The transitions C1 and C4 are spin-flipping transitions. Transition C1 is between the spin up state |↑′> of the lower excited state 212 and the spin down state |↓> of the lower ground state 202. Transition C4 is between the spin down state |↓′> of the lower excited state 212 and the spin up state |↑ [symbol] of the lower ground state 202.

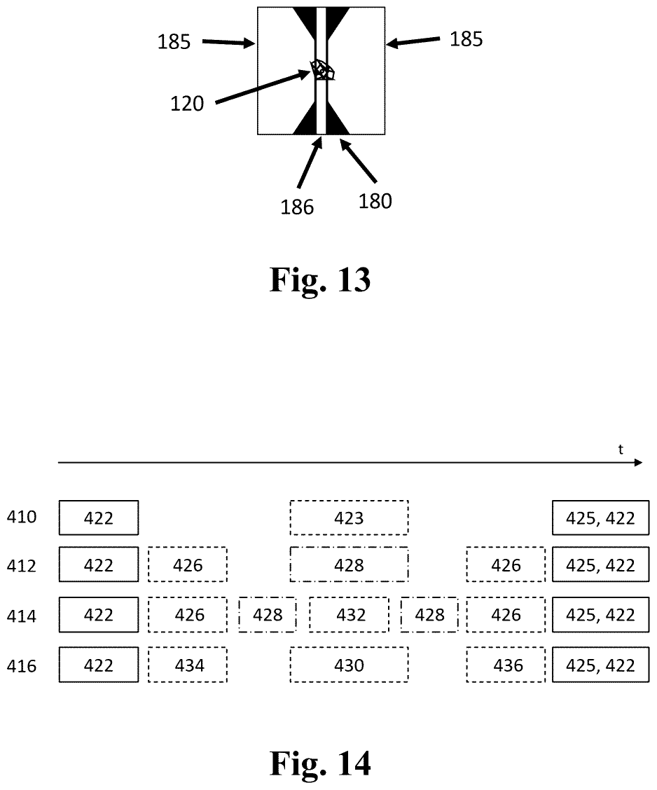

Quantum information can be stored in the spin object 170, in particular the carbon-13 isotope 173 in the nanodiamond 120 of the quantum memory unit 100 as follows: The levels |↓ [symbol] [symbol] and |↓ [symbol] [symbol] as seen in FIG. 7 act as the two qubit levels. Any state, in particular any arbitrary coherent superposition of these two qubit states, can be created by the above-mentioned control mechanisms. Such a state can be manipulated by using an RF field which is resonant to the energy difference which is called ground state composite spin spitting 230. It is further possible to swap from |↓ [symbol] [symbol] and |↓ [symbol] [symbol] as will be described below with reference to FIG. 14 and a XY-N sequence 416.

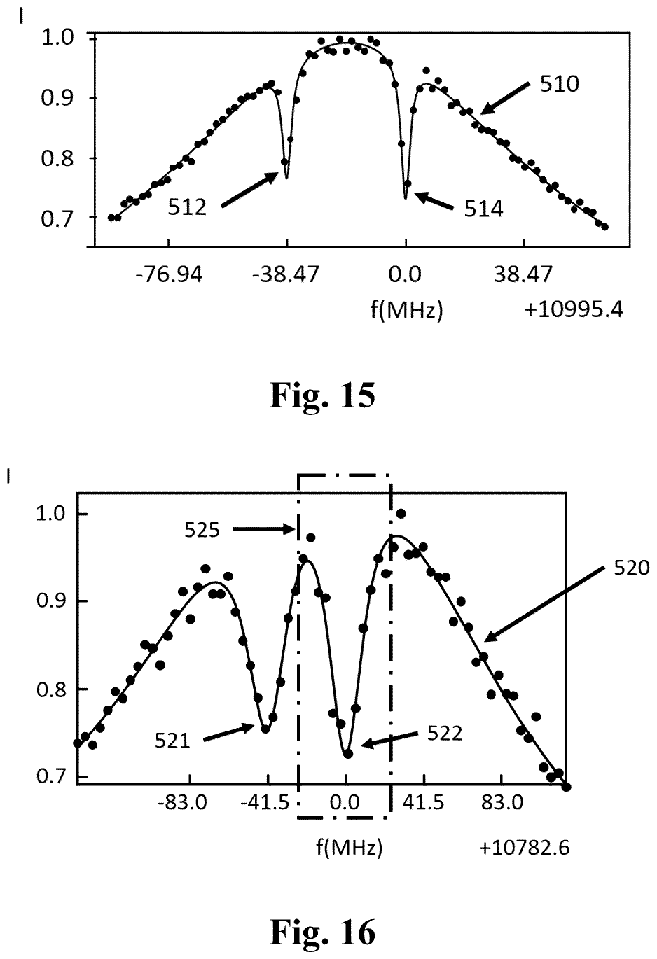

In the quantum memory unit 100, a coupling rate of the electron spin of the SiV⁻ center 150 to the nuclear spin of the carbon-13 isotope 173 is larger than a decoherence rate of the electron spin. This feature will be explained in connection with FIGS. 15 to 17.

FIG. 9 shows a schematic illustration of a different embodiment of the quantum memory unit 100 of FIG. 1 wherein the electron spin of the SiV⁻ center 150 is coupled to the spin object 170 which is located outside of the nanodiamond 120 or on the surface of the nanodiamond 120. The spin object 170 here is also a non-zero nuclear spin of a carbon-13 isotope 173.

According to another embodiment (not shown here), the electron spin of the quantum emitter 140 is coupled to the spin object 170 which is located inside of the nanodiamond 120. The quantum memory unit 100 further comprises a second spin object outside of the nanodiamond 120, wherein the electron spin of the quantum emitter 140 is coupled to a spin of the second spin object, and wherein a coupling rate of the spin of the spin object 170 to the electron spin of the quantum emitter 140 is larger than a decoherence rate of the electron spin of the quantum emitter 140. The coupling to the second spin object has the advantage that quantum information stored inside the nanodiamond can via the second spin object outside of the nanodiamond 120 be coupled to external quantum platforms such as, for example, superconducting technology, thereby creating an interface between different processor units and/or memory units.

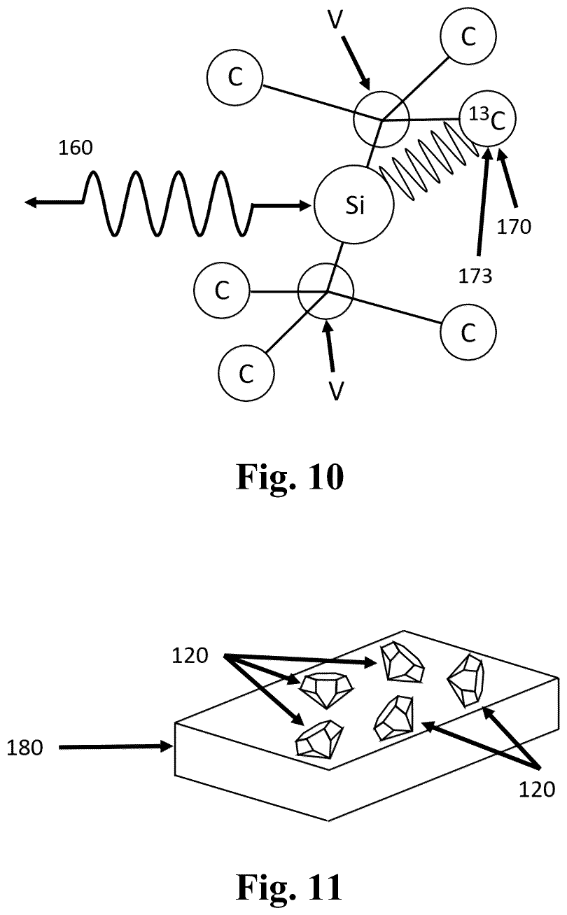

FIG. 10 illustrates how a SiV⁻ center 150, in particular the electron spin, of a quantum memory unit 100 acts as a mediator or broker between a flying qubit 160 coming from outside of the nanodiamond 120 and the spin object 170 inside the nanodiamond 120. The electron spin of the SiV⁻ center 150 and the spin object 170 are designed and configured so that quantum information can be transferred from a flying qubit 160 to the spin object 170 and from the spin object 170 to the flying qubit 160.

An experimental setup to realize a quantum memory unit 100 and in particular to measure important features of the quantum memory unit 100, such as the coupling rate of the electron spin to the spin object 170 and the decoherence rate of the electron spin, is shown in FIGS. 11 to 13.

The nanodiamonds 120 are produced and coated onto a sapphire substrate 180 to provide good thermal conductivity (see FIG. 11). The substrate 180 is placed inside a continuous flow cryostat 320 and cooled to liquid helium temperatures. A home-built confocal microscope is used to investigate the nanodiamonds 120 on the substrate 180. An atomic force microscope scan of the nanodiamonds 120 containing the investigated the SiV⁻ center 150 revealed an agglomeration of nanodiamonds 120.

The experimental setup shown in FIG. 12 is explained below.

A laser 340 is used to excite the nanodiamonds 120 inside the cryostat 320. For reasons of simplicity, only one nanodiamond 120 is reproduced in FIGS. 12 and 13.

The laser 340 may e.g. be a Ti: sapphire laser, which may operate at 737 nm and can be tuned over a range of more than 80 nm. The linewidth of the laser is narrow enough to address individual transitions of the SiV⁻ center 150.

The laser beam emerging from the laser 340 is modulated by a modulator 342 which may be an acousto-optic modulator (AOM) or an electro-optic modulator (EOM). The modulator 342 may be used to chop the signal of the laser 340, thus creating laser pulses of adjustable length. The laser 340 may alternatively be used to create sidebands with a desired frequency offset, which also can be adjusted.

The modulated laser beam is reflected by a mirror 356, passes through a halfwave plate 362, and is then reflected by a beamsplitter cube 358 towards a beam sampler 364. A beam sampler is an optical device that utilizes the Fresnel reflection from an uncoated optical surface to pick off a small percentage of an incident beam, depending on the incident light's polarization. This is advantageous for applications where optical losses and wavefront distortions of the transmitted beam need to be kept to a minimum. The laser beam which is reflected from the beam sampler 364 is focused inside an objective 332 which is located inside the cryostat 320 using a galvo scanner 350 and two lenses 346. A microwave source 344 which is fixed to the substrate 180 can be used to expose the nanodiamonds 120 to microwave radiation.

Light which is emitted from one nanodiamond 120 goes back the same path as the laser beam exciting the nanodiamonds 120 until the beam sampler 364. Because the beam sampler 364 is transparent for the emitted light from the nanodiamond 120, the emitted light will go through the beam sampler 364, get reflected at another mirror 356, and is filtered by a long pass filter 361. Long pass filter 361 is basically transparent for wavelengths larger than 750 nm which for the present set up means that laser light which is used for exciting a transition of the SiV⁻ center 150 and which is reflected by any optical element in the beam path will not go through the long pass filter 361 and will not thereafter disturb the measurement. The filtered light is then coupled into a single mode fiber 369 using a fiber coupler 366. At the end of the single mode fiber 369, light is collected and detected by a single photon counting module (SPCM) 368.

FIG. 13 shows a top view of the substrate 180 including the nanodiamonds 120 as an enlarged view of the part of the experimental setup which is shown in FIG. 12 inside circle 371.

The nanodiamonds 120 are placed on the substrate 180 on top of a microwave structure which comprises gold layers which are coated onto the substrate 180. The microwave structure comprises a large flat two-part section 185 and a small strip like section 186. The nanodiamonds 120 are placed on the small strip like section 186. In this top view of FIG. 13, the substrate 180 can only be seen in a smart part which is colored in black. A center conductor core of a coaxial cable connected to the microwave source 344 is connected to the strip like section 186. A shield of the coaxial cable, i.e., the ground, is connected to both parts of section 185. The shape of the microstructure is such that the microwave radiation is efficiently coupled to the inside of the nanodiamond 120.

FIG. 14 shows different methods or pulse sequences which are used to realize a quantum memory unit 100 or to measure important features of the quantum memory unit 100.

FIG. 14 schematically shows four sequences 410, 412, 414 and 416 as a function of time t. Each box represents one element of the above-mentioned sequence. A box having a solid line is a pulse or an activity using or involving laser radiation. A box having a dashed line is a pulse or an activity using or involving microwave and/or RF radiation. A box having a dash-dotted line is presenting a waiting time.

Sequence 410 is a Rabi pulse sequence which can be used to determine the Rabi frequency for the used transition and the used light field or intensity.

Sequence 412 is a Ramsey pulse sequence which may be used to measure the spin the decoherence time.

Sequences 414 and 416 are dynamical decoupling sequences which are known in the field of NMR and which can be used to suppress decoherence. This means that if such a dynamical decoupling sequence is used to measure the decoherence rate of the electron spin, that the measured decoherence rate is lower than a decoherence rate which was measured without such a dynamic decoupling sequence.

Sequence 414 is a Hahn echo pulse sequence which may alternatively be called spin echo. Sequence 416 is an XY-N sequence.

According to the Rabi pulse sequence 410, an initialization pulse 422 is first applied to the quantum memory unit 100.

In order to do this, one of the spin-cycling transitions, for example, the transition from the spin down state |↓> of the lower ground state 202 to the spin down state |↓′> of the lower excited state 212 was used to optically pump the spin into the spin up state |↑> of the lower ground state 202 within a given amount of time τₚᵤₘₚ. This is due to the fact that the state |↓′> decays with a low probability into the desired spin up state |↑ [symbol] , which can then no longer be driven by the laser. At the beginning of the measurement, the spin is distributed almost evenly between the spin up state |↑ [symbol] and the spin down state |↓ [symbol] , i.e., 50% to 50%, in a thermal equilibrium. The spin is then pumped into a state with a certain probability, usually referred to as fidelity, in the present case in the spin up state |↑ [symbol] . In the next step, a microwave pulse 423 is applied to the quantum memory unit 100. The fidelity may, for example, be 90%.

The microwave pulse 423 has a duration time τ_{MW}, whose frequency v_{MW} is resonant with the energy difference between the spin up state |↑ [symbol] and the spin down state |↓ [symbol] . In the case of a free electron spin, this energy difference would be equal to the so-called Zeeman splitting. The temporally alternating magnetic field B_{MW}(t) of the microwave can now couple to the intrinsic magnetic moment μₛ of the electron spin, provided that the magnetic field is partially polarized orthogonally to the external DC field B₀, in the best case B_{MW}(t) is orthogonal to the external DC field B₀. The associated coupling strength Ω is proportional to the product of the driving field and magnetic moment, i.e., Ω∝μ_{S}B_{MW}. Ω may also be called Rabi frequency. If the Rabi frequency is greater than the intrinsic decoherence rate of the electron spin, coherent rotations, also known as Rabi oscillations, are driven from the spin up state |↑ [symbol] to the spin down state |↓ [symbol] . In the simplest case, the angle of rotation Θ is related to the Rabi frequency as follows: Θ=Ω·τ_{MW}. A rotation angle of π corresponds to a complete inversion of the spin state, for example, from the spin up state |↑ [symbol] to the spin down state |↓ [symbol] .

In the following step, the spin state is read out using the same pulse which was used for initialization. This means that the read pulse 425 is the same as the initialization pulse 422.

This utilizes the fact that the resonant laser generates detectable fluorescence exactly when the corresponding state driven by the laser is occupied. The fluorescence in this case is therefore high when the spin is in the spin down state |↓ [symbol] , which means that the laser drives the transition from the spin down state |↓> of the lower ground state 202 to the spin down state |↓′> of the lower excited state 212.

If this experiment is repeated with different microwave durations τ_{MW}, the oscillation mentioned above can be measured so that the oscillation period of one Rabi oscillation can be determined. In an example measurement, it was determined that the duration it takes for the microwave to invert the spin, i.e., a π pulse, is half of 609.4 ns. If the microwave duration is a quarter of 609.4 ns, a superposition of the spin up state |↑ [symbol] and the spin down state |↓ [symbol] is prepared. The preparation of a superposition state, which might as well be visualized on the equator of the Bloch sphere, forms the basis for the other pulse sequences of the present drawing.

The Ramsey pulse sequence 412 starts with the same initialization pulse 422 as the Rabi pulse sequence 410. After step 422, the spin is in the spin up state |↑ [symbol] with the above-mentioned fidelity.

The following step 426 is a π/2 pulse, which generates a superposition of the spin up state |↑ [symbol] and the spin down state |↓ [symbol] . The decoherence can be measured using a waiting step 428, which waits for a given amount of time τ_{Ramsey}. For this purpose, another π/2 pulse 426 is applied after the waiting step 428 with subsequent readout of the respective spin state populations by the laser in the readout step 425.

In an example measurement, the coupling of the electron spin to a nearby nuclear spin with a coupling strength of A_{∥}~600 kHz leads to a splitting of the electron spin resonances. The microwave frequency here is detuned by A_{∥}/2, which is why an oscillation with this frequency can be seen in the measured data (which is not here reproduced). The exponential attenuation constant can be identified as the decoherence time, which is caused, for example, by noise in a diffuse nuclear spin environment. The coherence time was here measured to be approximately 3 μs.

Depending on the frequency and strength of the spin noise, parts of the noise can be decoupled from the signal using special pulse sequences.

For this purpose, It pulses with variable microwave phase φ, which is relative to the first π/2 pulse, are added between the first π/2 pulse, which prepares the superposition, and the last π/2 pulse, which then transforms general states on the equator to measurable spin populations. This is referred to as dynamical decoupling.

If there is only one π pulse, we speak of a Hahn echo. Several π pulses with a relative phase of φ=π/2 are referred to as CPMG.

If relative phases of 0 and π/2 occur, which are often indexed with a subscript of x or y, i.e., πₓ, π_{y}, this sequence is referred to as an XY-N sequence. The latter has the additional advantage that amplitude errors of the microwave can also be corrected. The shorter the waiting time τ between two consecutive π pulses, the higher frequency noise can be decoupled.

The Hahn echo pulse sequence 414 starts with the same initialization pulse 422 as the Rabi pulse sequence 410. After step 422, the spin is in the spin up state |↑ [symbol] with the above-mentioned fidelity. In the following step 426, a π/2 pulse is applied so that the spin state is on the equator of the Bloch sphere. The next step 428 is a waiting pulse which waits for a given amount of time τ. During that time, different realizations of the same quantum state evolve randomly by picking up noise from the environment. The next step 432 is a π pulse which rotates the Bloch sphere around the horizontal axis for 180° so that the relative population stays unchanged and the relative phases pick up a minus sign. The following step is again a waiting pulse 428 which waits for a given amount of time τ. The different relative phases are now again picking up a random phase during the waiting pulse, which ideally is the same as during the first waiting pulse 428, so that all total phases cancel out. The following step 426 is another π/2 pulse, which under ideal circumstances rotates the different realizations back to the pole of the Bloch sphere where it started. The spin state is read out in the last step 422, 425.

In an example measurement for the Hahn echo pulse sequence 414, a coherence time of 42 μs was measured which is clearly longer than the coherence time of 3 μs which was measured with the Ramsey pulse sequence 412 above. There are resonances occurring in the dynamic decoupling sequence due to the above-mentioned coupling to a nucleus in the vicinity with hyperfine coupling strengths of e.g. A_{∥}~600 kHz, A_{⊥}~150 kHz. After a certain waiting time t, the associated nucleus may therefore be rotated due to its coupling to the electron spin. This leads to an entanglement between the nuclear spin and the electron spin, which results in a dip in the electron spin coherence.

The XY-N sequence 416 starts with the same initialization pulse 422 as the Rabi pulse sequence 410. After step 422, the spin is in the spin up state |↑ [symbol] with the above-mentioned fidelity. The following step 434 is a π_{y}/2 pulse, i.e., a π/2 pulse about the y axis of the Bloch sphere. The next step 430 is a pulse sequence which comprises N times the sequence which comprises the following step in this order: waiting time τ, πₓ pulse, waiting time 2·τ, π_{y} pulse, waiting time 2·τ, πₓ pulse, waiting time 2·τ, π_{y} pulse, waiting time 2·τ, π_{y} pulse, waiting time 2·τ, πₓ pulse, waiting time 2·τ, π_{y} pulse, waiting time 2·τ, πₓ pulse, waiting time τ. In the next step 436, a 3/2·π_{y} pulse is applied. The XY-N sequence 416 may alternatively be called a XY8-N sequence as it comprises 8 π pulses, i.e., 4 πₓ and 4 π_{y} pulses. The spin state is read out in the next and final step 422, 425.

An example measurement of the XY-N sequence 416 was also performed with the present set up. The coherence time was here measured to be approximately 100 μs.

This example measurement showed resonances. These resonances are a consequence of the rotation of the nucleus due to the coupling to the electron spin, which is repeatedly inverted by the π pulses. If the electron spin is now prepared in an initially predetermined state, a sequence of quantum operations on the electron can be used to rotate the nucleus into an arbitrary state. The electron spin state can in particular be “swapped” onto the nucleus using a special sequence of quantum operations. That means that after the swap, the quantum state of the electron spin will be the quantum state of the nuclear spin before the swap and the quantum state of the nuclear spin after the swap will be the quantum state of the electron spin before the swap.

This indirect manipulation of the nuclear spin via the electron spin also allows, for example, the initialization of the nuclear spin, which initially is similar to the electron spin in a statistical mixture of 50% in the nuclear spin up state | [symbol] [symbol] and 50% in the nuclear spin down state | [symbol] [symbol] . Subsequent indirect rotations of the nuclear spin allow the achievement of an arbitrary preparation of the nuclear spin into a general state. This means that the nuclear spin can be rotated analogously to the above-mentioned Rabi oscillations of the electron spin.

In an example measurement of Rabi oscillations of the nuclear spin, the nuclear spin is first initialized indirectly, then rotated, and finally read out. It was observed that it takes about 160 π pulses on the electron spin for the nuclear spin to make a complete Rabi oscillation. This means that it takes about 40 π pulses on the electron spin to prepare the nuclear spin in as superposition of 50% in the nuclear spin up state | [symbol] [symbol] and 50% in the nuclear spin down state | [symbol] [symbol] .

FIG. 15 shows a coherent population trapping (CPT) measurement of one SiV⁻ center 150 which is strongly coupled to one nuclear spin of a carbon-13 isotope 173. The goal of this experiment was to measure the decoherence rate of the electron spin or the spin coherence time T2. The SiV⁻ center 150 under investigation was part of the above-mentioned agglomeration.

Coherent population trapping (CPT) was used to probe or measure the spin-coherence. The laser thereby resonantly drives a spin-flipping transition, i.e., the transition C1 or C4 shown in FIG. 8. The electro-optical modulator (EOM) 342 simultaneously generates sidebands from which one is swept over the corresponding spin-preserving transition, i.e., transition C2 or C3. If the Raman condition is fulfilled, the system is pumped into a dark state quenching the fluorescence signal. FIG. 15 shows the fluorescence signal 510 of the CPT measurement. The fluorescence signal 510 shows an intensity signal I in arbitrary units which are normalized to the maximum intensity. The fluorescence signal 510 comprises measurement points which are reproduced as dots. The curve was fitted to the measurement points using a triple Lorentzian fitting function. The fluorescence signal 510 is plotted against the frequency difference between the frequency of a generated sideband and the frequency of the laser with a given offset. The offset is here indicated at the bottom right edge of FIG. 15. The offset is 10,995.4 MHz. For the SiV⁻ center 150 under consideration, the two dips 512, 514 with a frequency splitting of A=(38.47±0.12) MHz were present. The splitting is in close agreement with a theoretically predicted strongly hyperfine-coupled next-nearest neighbor carbon-13 nuclear spin with a coupling strength of A_{∥}=37 MHz.

The two dips are created as follows. Transition C4 is driven constantly and one sideband generated by the electro-optic modulator (EOM) 342 is swept over transition C2.

Because of the nearby nuclear spin of the carbon-13 isotope 173, two independent lambda (Λ) schemes arise which each form a typical coherent population trapping (CPT) dip. The first lambda (Λ) scheme comprises the levels |↓ [symbol] [symbol] , |↓′ [symbol] [symbol] and |↑ [symbol] [symbol] . The second lambda (Λ) scheme comprises the levels |↓ [symbol] [symbol] , |↓′ [symbol] [symbol] and |↑ [symbol] [symbol] . Both the first lambda (Λ) scheme and the second lambda (Λ) scheme may be driven by Raman transitions. These two Raman transitions occur at different frequencies which can be seen in FIG. 7.

Since the dip's linewidth gives insight on the spin's decoherence rate, a power dependent measurement thereof was performed. Fitting the data with a Lorentzian and extracting the linewidth Γ₂ allowed to linearly extrapolate the decoherence rate to zero laser power to exclude power induced broadening. A zero power linewidth of Γ₂=(320±120) kHz was obtained as a result. That is equivalent to a spin coherence time T2 of about 0.5 μs. This is approximately a ten-fold reduced decoherence rate compared to previously reported measurements in bulk diamonds at similar temperatures. Considering the latter improvements of spin coherence in high strain environments, the spin transition frequency of roughly 11 GHz and the spin-cycling transitions' splitting of 390 MHz suggests a comparably highly strained SiV⁻, resulting in a GS splitting in the order of 500 GHz.

The coupling rate of the electron spin to the spin object A in the present embodiment is larger than the decoherence rate Γ₂ of the electron spin by a factor of about 120.

The spin environment in the same agglomeration of nanodiamonds 120 was further investigated by performing further CPT measurements on different SiV⁻ centers 150.

FIG. 16 shows another coherent population trapping (CPT) measurement which was performed in the same manner as the measurement shown in FIG. 15.

The fluorescence signal 520 shows an intensity signal I in arbitrary units which are normalized to the maximum intensity. The fluorescence signal 520 is plotted against the frequency difference between the frequency of a generated sideband and the frequency of the laser with a given offset. In contrast to the embodiment of FIG. 15, the offset indicated at the bottom right edge of FIG. 16 is here 10,782.6 MHz.

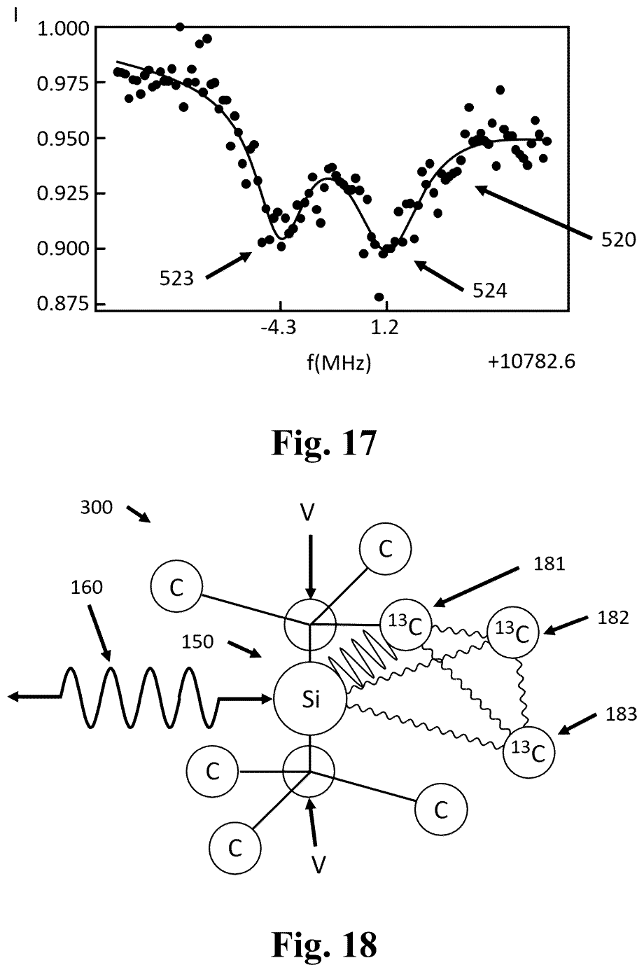

The fluorescence signal 520 of FIG. 16 shows two dips 521, 522 split by A=(41.5±0.7) MHz. Measurements of dip 522 with reduced power resolved two more dips 523, 524, split by A′=(5.47±0.17) MHz, as shown in FIG. 17. The measurements with reduced power shown in FIG. 17 correspond to the part of FIG. 16 which is marked by a frame 525 with a dash-dotted line. Dip 523 has a linewidth of (3.2±0.4) MHz and dip 524 has a linewidth of (4.3+0.5) MHz. Dip 521 was also measured with reduced power and also resolved two more dips (which are here not reproduced).

This means that two spin objects are coupled to the quantum emitter 140. For example, one spin object could be coupled with a coupling rate of approximately 44.2 MHz and the other spin object could be coupled with a coupling rate of approximately 38.8 MHz coupling rate coupled to the first spin object.

One spin object could alternatively be coupled with a coupling rate of approximately 41.5 MHz and the other spin object could be coupled with a coupling rate of approximately 5.47 MHz to the first spin object.

The distinct linewidths suggest coupling to two other electron spins of surrounding SiV⁻ centers 150, which have different coherence properties commonly found with only moderate strain. Assuming a dipolar electron-electron coupling, this would correspond to a distance on the order of a few nm, which is reasonable for the size of the nanodiamond 120 and the density of SiV⁻ centers 150 under study.

This measurement shows that the system which was measured in FIGS. 16 and 17 is a quantum register unit 300 because the electron spin of the SiV⁻ center 150 is coupled to two non-zero spin objects which are the nuclear spins of two carbon-13 isotopes 173 inside of the nanodiamond 120.

FIG. 18 shows an embodiment of the quantum register unit 300. A first spin object 181, which is a carbon-13 isotope, is strongly coupled to the electron spin of the SiV⁻ center 150, while the coupling of the second and third spin objects 182, 183 to the electron spin of the SiV⁻ center 150 is weaker. The coupling of the three spin objects 181, 182, 183 to each other is also weak which is indicated by the low amplitude of the curved lines connecting the three spin objects 181, 182, 183 with each other. Each spin object 181, 182, 183 can be used to store quantum information, quantum information can be retrieved therefrom, and the quantum states of the spin objects can also be manipulated.

A flying qubit 160 can also be used to exchange quantum information of the flying qubit 160 with the SiV⁻ center 150 of the quantum register unit 300. The meaning of the term “exchange quantum information” may comprise the transfer of and retrieval of quantum information. Quantum information of the SiV⁻ center 150 of the quantum register unit 300 may in turn be exchanged with one of the three non-zero spin objects 181, 182, 183.

As in the previous embodiments in FIG. 15, the coupling rate A of the electron spin, which is 5.2 MHz in the present case, is here larger than the decoherence rate of the electron spin which is about 2.2 MHz here.

FIG. 19 shows another coherent population trapping (CPT) measurement which was performed in the same manner as the measurements shown in FIGS. 15 to 17.

The fluorescence signal 530 shows an intensity signal I in arbitrary units which are normalized to the maximum intensity. The fluorescence signal 530 is plotted against the frequency difference between the frequency of a generated sideband and the frequency of the laser with a given offset. In contrast to the embodiment of the preceding drawings, the offset indicated at the bottom right edge of FIG. 19 is here 10,896.8 MHz.

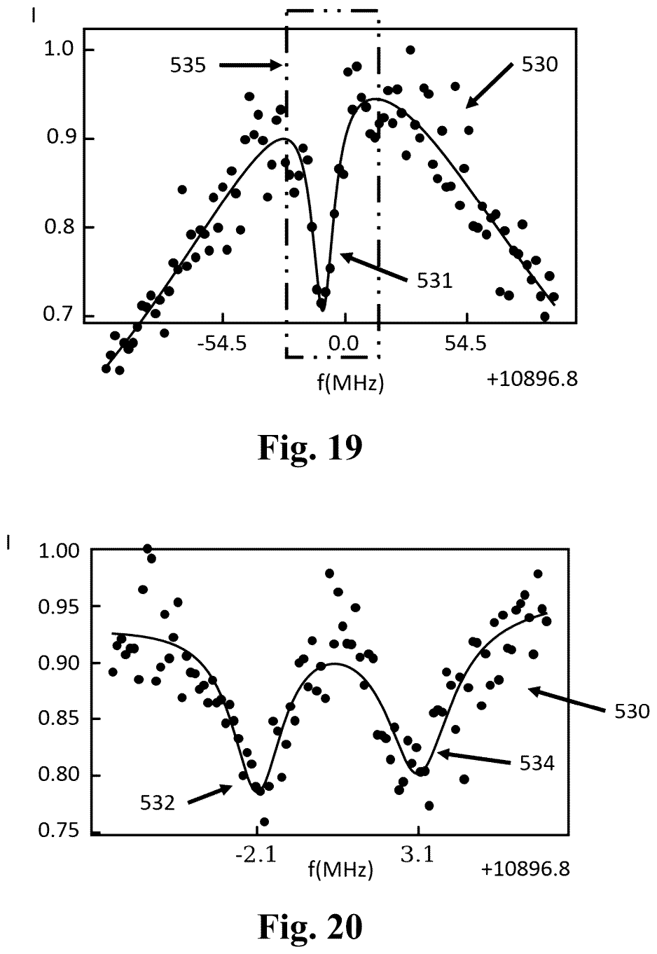

The fluorescence signal 530 of FIG. 19 shows that one SiV⁻ center 150 is coupled to one nuclear spin of a carbon-13 isotope 173. The fluorescence signal 520 of FIG. 19 shows a single dip 531. Measurements of dip 531 with reduced power resolved two more dips 532, 534, split by A=(5.20±0.14) MHz, as shown in FIG. 20. The measurements with reduced power shown in FIG. 20 correspond to the part of FIG. 19 which is marked by a frame 535 with a dash-dotted line. Dip 532 has a linewidth of (2.0±0.3) MHz and dip 524 has a linewidth of (2.6±0.5) MHz. The linewidths of dips 532 and 534 match within their respective error bars and correspond to the decoherence rate of the electron spin.

In contrast to the multi-dip structure of the SiV⁻ center 150 of the embodiment of FIGS. 16 and 17 with distinct linewidths, the fact that the present SiV⁻ center 150 has closely matching as well as relatively narrow linewidths is indicative of a weakly coupled nearby carbon-13 nuclear spin with a coupling strength of 5.2 MHz. The distance between the two coupled spins in this case is on the order of 1 Å.

As in the previous embodiments in FIG. 15, the coupling rate A of the electron spin, which is here 5.2 MHz, is here larger than the decoherence rate of the electron spin, which is in this case about 2.2 MHz.

The present invention is not limited to embodiments described herein; reference should be had to the appended claims.

### LIST OF REFERENCE CHARACTERS

100 Quantum memory unit
120 Nanodiamond
140 Quantum emitter
150 Silicon vacancy (SiV⁻) center
160 Flying qubit
170 Spin object
173 Carbon-13 isotope
180 Substrate
181 First spin object
182 Second spin object
183 Third spin object
185 Large flat two-part section
186 Small strip like section
200 Ground state
202 Lower ground state
204 Upper ground state
210 Excited state
212 Lower excited state
214 Excited upper state
220 Ground state spin spitting
222 Excited state spin spitting
230 Ground state composite spin spitting
232 Excited state composite spin spitting
300 Quantum register unit
320 Cryostat
332 Objective
340 Laser
342 Modulator/Electro-optic modulator (EOM)
344 Microwave source
346 Lens
350 Galvo scanner
356 Mirror
358 Beamsplitter cube
361 Long pass filter
362 Halfwave plate
364 Beam sampler
366 Fiber coupler
368 Single photon counting module
369 Single mode fiber
371 Circle
410 Rabi pulse sequence
412 Ramsey pulse sequence
414 Hahn echo pulse sequence/Spin echo
416 XY-N sequence
422 Initialization pulse
423 Microwave pulse
425 Read pulse
426 π/2 pulse
428 Waiting pulse
432 π pulse
434 π/2 pulse
430 pulse sequence
510 Fluorescence signal
512 Dip
514 Dip
520 Fluorescence signal
521 Dip
522 Dip
523 Dip
524 Dip
525 Measurements with reduced power
530 Fluorescence signal
531 Dip
532 Dip
534 Dip
535 Measurements with reduced power
A Transition
B Transition
C Transition
C1-4 Transitions of C
D Transition
I Intensity
LW Line width
V Vacant lattice site
ΔES Excited state splitting
ΔGS Ground state splitting
λ Wavelength
t Time

What is claimed is

1-15. (canceled)

16. A quantum memory unit comprising:
a nanodiamond comprising a quantum emitter; and
a first spin object which is arranged inside of or outside of the nanodiamond,
wherein,
an electron spin of the quantum emitter is coupled to the spin object,
a coupling rate of the electron spin of the quantum emitter to the first spin object is larger than a decoherence rate of the electron spin of the quantum emitter, and
the first spin object is configured so that,
a quantum information can be stored in the spin object,
the quantum information can be retrieved from the spin object, and/or
a quantum state of the first spin object can be manipulated.

17. The quantum memory unit as recited in claim 16, wherein,
the first spin object is a non-zero nuclear spin of an atom, or
the first spin object is an electron spin object.

18. The quantum memory unit as recited in claim 17, wherein the atom is a carbon-13 isotope, a Si-29 isotope, a N-15 isotope or an atom inside or outside of the nanodiamond having a non-zero nuclear spin.

19. The quantum memory unit as recited in claim 16, wherein a strain inside the nanodiamond is larger than a predetermined value so that a ground state splitting is larger than 46 GHz.

20. The quantum memory unit as recited in claim 19, wherein the ground state splitting is larger than 0.5 THz

21. The quantum memory unit as recited in claim 19, wherein,
a size of the nanodiamond is smaller than a wavelength of an optical transition of the quantum emitter, and/or
a size of the nanodiamond is smaller than a wavelength of a phonon in the nanodiamond corresponding to an energy of the ground state splitting.

22. The quantum memory unit as recited in claim 16, wherein the quantum emitter is a group IV color center.

23. The quantum memory unit as recited in claim 22, wherein the group IV color center is a single negatively charged silicon vacancy SiV⁻ center.

24. The quantum memory unit as recited in claim 16, further comprising:
a second spin object which is arranged outside of the nanodiamond,
wherein,
the electron spin of the quantum emitter is coupled to a spin of the second spin object, and
a coupling rate of the spin of the second spin object to the electron spin of the quantum emitter is larger than the decoherence rate of the electron spin of the quantum emitter.

25. The quantum memory unit as recited in claim 24, wherein the coupling rate of the electron spin of the quantum emitter to the first spin object is larger than 0.01 MHz.

26. The quantum memory unit as recited in claim 24, wherein the coupling rate of the electron spin of the quantum emitter to the first spin object is larger than 5 MHz.

27. The quantum memory unit as recited in claims 16, wherein the decoherence rate of the electron spin of the quantum emitter is smaller than an electron spin flip rate under driving.

28. The quantum memory unit as recited in claim 16, wherein,
the quantum memory unit is configured so that, in order to measure the decoherence rate of the electron spin of the quantum emitter, a pulse sequence and/or a dynamical decoupling sequence is applied to the quantum memory unit, and
a measured decoherence rate of the electron spin of the quantum emitter is smaller than 1 MHz.

29. The quantum memory unit as recited in claim 16, wherein a temperature of the nanodiamond is above 100 mK.

30. The quantum memory unit as recited in claim 16, wherein a temperature of the nanodiamond is above 5 K.

31. The quantum memory unit as recited in claim 16, wherein the quantum memory unit is configured so that the quantum state of the first spin object can be coherently manipulated and/or controlled by,
coherently controlling the electron spin of the quantum emitter, and/or
by applying microwave radiation or RF radiation to the first spin object.

32. The quantum memory unit as recited in claim 16, wherein the electron spin of the quantum emitter and/or the first spin object of the quantum memory unit is/are configured so that the quantum state of the first spin object can be coherently manipulated and/or controlled by,
coherently controlling the electron spin of the quantum emitter, and/or
by applying the microwave radiation or the RF radiation to the first spin object.

33. : The quantum memory unit as recited in claim 16, wherein the electron spin of the quantum emitter to the first spin object is configured so that the quantum information can be transferred from a flying qubit to the spin object and/or from the spin object to the flying qubit.

34. A quantum register unit comprising:
the quantum memory unit as recited in claim 16 which further comprises at least two spin objects,
wherein
the electron spin of the quantum emitter is coupled to the at least two spin objects,
the at least two spin objects are provided as different spin objects which are arranged inside of and/or outside of the nanodiamond,
a coupling rate of the electron spin of the quantum emitter to each of the at least two spin objects is larger than the decoherence rate of the electron spin of the quantum emitter, and
each of the at least two spin objects is configured so that quantum information can be stored therein, retrieved therefrom, and/or so that a quantum state of a spin object can be manipulated.

35. The quantum register unit as recited in claim 34, wherein,
at least one of the at least two spin objects is coupled to at least another one of the at least two spin objects, and
a coupling rate between the at least one of the at least two spin objects and the at least another one of the at least two spin objects is larger than a largest decoherence rate of the at least two spin objects.
